(19) United States
(12) Patent Application Publication
(10) Pub. No.: US 2013/0153268 A1
(43) Pub. Date: Jun. 20, 2013

(54) FASTENING APPARATUS FOR HEAT SINK

(71) Applicant: Lei LIU, Shenzhen City (CN)

(72) Inventor: Lei LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/337,315

(22) Filed: Dec. 27, 2011

(30) Foreign Application Priority Data
Dec. 20, 2011 (CN) 201110429483.3

(51) Int. Cl. H05K 7/20; H05K 7/14

(52) U.S. Cl. 174/252; 248/222.12

(57) ABSTRACT

A fastening apparatus for fastening a heat sink having a base to a circuit board includes two fasteners, two nuts, and two springs. Each fastener includes a head, a threaded pole extending down from a bottom of the head, and two spaced latching arms extending down from a bottom end of the threaded pole, for extending through the base and the circuit board to engage with a bottom surface of the circuit board. The nuts are respectively placed around and are engaged with the threaded poles, and movable up and down relative to the threaded pole. The springs are respectively placed around the threaded poles between the base and the corresponding nuts.

### BACKGROUND

1. Technical Field

The present disclosure relates to an apparatus for fastening a heat sink.

2. Description of Related Art

To fasten a heat sink to a motherboard having an electronic component, a number of fasteners are provided to respectively extend through a number of springs and the heat sink, and then are engaged in the circuit board, to fasten the heat sink on the electronic component. However, when the motherboard or the electronic component is too thick, the fasteners may be not long enough to fasten the heat sink to the motherboard. On the other hand, when the motherboard or the electronic component is too thin, the fasteners may be too long to compress the springs, therefore, the fasteners are loose and cannot fasten the heat sink tightly to the motherboard.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a fastening apparatus together with a heat sink and a circuit board.

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

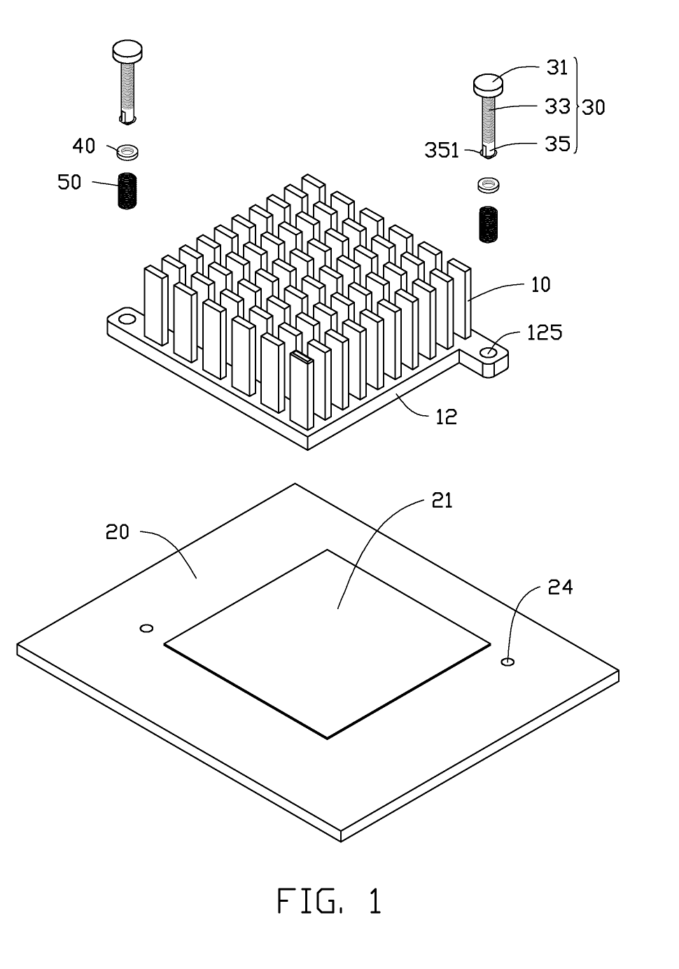

FIG. 1, is an exemplary embodiment of a fastening apparatus to fasten a heat sink 10 to a circuit board 20 having an electronic component 21. The fastening apparatus includes two fasteners 30, two nuts 40, and two springs 50.

The heat sink 10 includes a base 12. Two first through holes 125 are defined in the base 12, respectively at two opposite corners of the base 12.

The circuit board 20 defines two second through holes 24 respectively adjacent to two opposite corners of the electronic component 21.

Each fastener 30 includes a head 31, an elongated threaded pole 33 perpendicularly extending down from the bottom of the head 31, and two spaced latching arms 35 extending down from the bottom end of the threaded pole 33. A latching portion 351 protrudes from a distal end of each latching arm 35, away from the opposite latching arm 35.

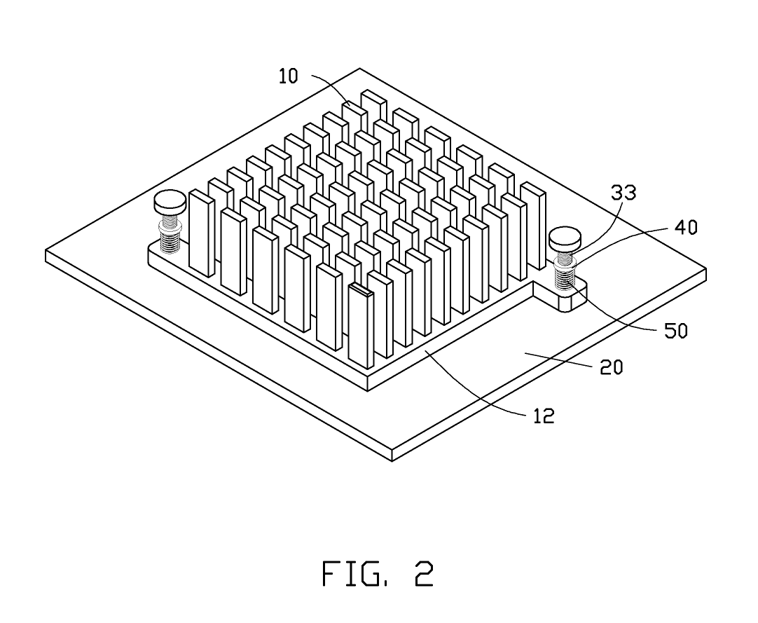

FIG. 2, in assembly, the nuts 40 are respectively placed around and are engaged with upper sections of the threaded poles 33. The springs 50 are respectively placed around the threaded poles 33 below the corresponding nuts 40. The latching arms 35 of each fastener 30 are deformed toward each other to extend through a corresponding first through hole 125 and a corresponding second through hole 24 in that order. The latching arms 35 then self-restore to allow the latching portions 351 to engage with the bottom of the circuit board 20. The nuts 40 are operated to move downwards, until the nuts 40 respectively abut against the tops of the springs 50, and the bottom of the base 12 completely contacts with the electronic component 21. Thereby, the heat sink 10 is tightly fastened to the circuit board 20.

When the thickness of the electronic component 21 and the circuit board 20 is changed, the nuts 40 can be moved down or up to allow the springs 50 to always be compressed between the base 12 and the corresponding nuts 40.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fastening apparatus for fastening a heat sink having a base to a circuit board, the fastening apparatus comprising:
two fasteners each comprising a head, a threaded pole extending down from a bottom of the head, and two spaced latching arms extending down from a bottom end of the threaded pole, for extending through the base and the circuit board to engage with a bottom surface of the circuit board;
two nuts respectively placed around and engaged with the threaded poles, wherein the nuts are movable up and down relative to the threaded pole through threaded portions of the nuts and the threaded poles; and
two springs respectively placed around the threaded poles between the base and the corresponding nuts.

2. The fastening apparatus of claim 1, wherein a latching portion protrudes from a distal end of each latching arm, away from the opposite latching arm.

3. A heat sink assembly, comprising:
a circuit board;
a component mounted on the circuit board;
a heat sink comprising a base in thermal contact with the component;
two fasteners each comprising a head, a threaded pole extending down from a bottom of the head, and two spaced latching arms extending down from a bottom end of the threaded pole, for extending through the base and the circuit board to engage with a bottom surface of the circuit board;
two nuts respectively placed around and engaged with the threaded poles, wherein the nuts are movable up and down relative to the threaded pole through threaded portions of the nuts and the threaded poles; and
two springs respectively placed around the threaded poles between the base and the corresponding nuts.

4. The heat sink assembly of claim 3, wherein a latching portion protrudes from a distal end of each latching arm, away from the opposite latching arm.
